(19) United States
(12) Patent Application Publication
(10) Pub. No.: US 2025/0208363 A1
(43) Pub. Date: Jun. 26, 2025

(54) OPTICAL DEVICES AND METHODS OF MANUFACTURE

(71) Applicant: Taiwan Semiconductor Manufacturing Co., Ltd., Hsinchu (TW)

(72) Inventors: Zi-Jheng Liu, Taoyuan City (TW); Tu-Hao Yu, Hsinchu (TW); Ming-Fa Chen, Taichung City (TW)

(21) Appl. No.: 18/627,789

(22) Filed: Apr. 5, 2024

Related U.S. Application Data
(60) Provisional application No. 63/613,240, filed on Dec. 21, 2023.

(51) Int. Cl. G02B 6/42

(52) U.S. Cl. CPC G02B 6/4283; G02B 6/4215; G02B 6/424

(57) ABSTRACT

Optical devices and methods of manufacture are presented in which optical interposers are formed with facets. In some embodiments a method includes receiving a first optical interposer bonded to a first semiconductor device, attaching a support substrate to the first semiconductor device, forming a facet recess to recess a sidewall of the first optical interposer and expose the support substrate, and forming a first spacer along a sidewall of the first optical interposer after the forming the facet recess.

### PRIORITY CLAIM AND CROSS-REFERENCE

This application claims the benefit of U.S. Provisional Application No. 63/613,240, filed on Dec. 21, 2023, entitled “COUPE EC-FACET STRUCTURE,” which application is hereby incorporated herein by reference.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates formation of an optical interposer, in accordance with some embodiments.

FIG. 2 illustrates a first gap fill material, in accordance with some embodiments.

FIG. 3 illustrates bonding of a first semiconductor device to the optical interposer, in accordance with some embodiments.

FIG. 4 illustrates a bonding of a support substrate, in accordance with some embodiments.

FIG. 5 illustrates a removal of a substrate, in accordance with some embodiments.

FIGS. 6A-6B illustrate formation of passivation layers, in accordance with some embodiments.

FIG. 7 illustrates formation of a first facet, in accordance with some embodiments.

FIG. 8 illustrates deposition of a material for a first spacer, in accordance with some embodiments.

FIG. 9 illustrates formation of a first spacer, in accordance with some embodiments.

FIGS. 10A-10C illustrate formation of a redistribution layer, in accordance with some embodiments.

FIG. 11 illustrates a singulation, in accordance with some embodiments.

FIG. 12 illustrates a grating coupler within the optical interposer, in accordance with some embodiments.

FIG. 13 illustrates attachment of a fiber array unit, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which a facet structure is incorporated into an optical interposer in order to help provide an optical interconnect to the optical interposer. However, the embodiments presented herein are intended to be illustrative and are not intended to limit the embodiments to the precise descriptions as discussed. Rather, the embodiments discussed may be incorporated into a wide variety of implementations, such as silicon photonics in general, or 3-D ICs with photonic applications, and all such implementations are fully intended to be included within the scope of the embodiments.

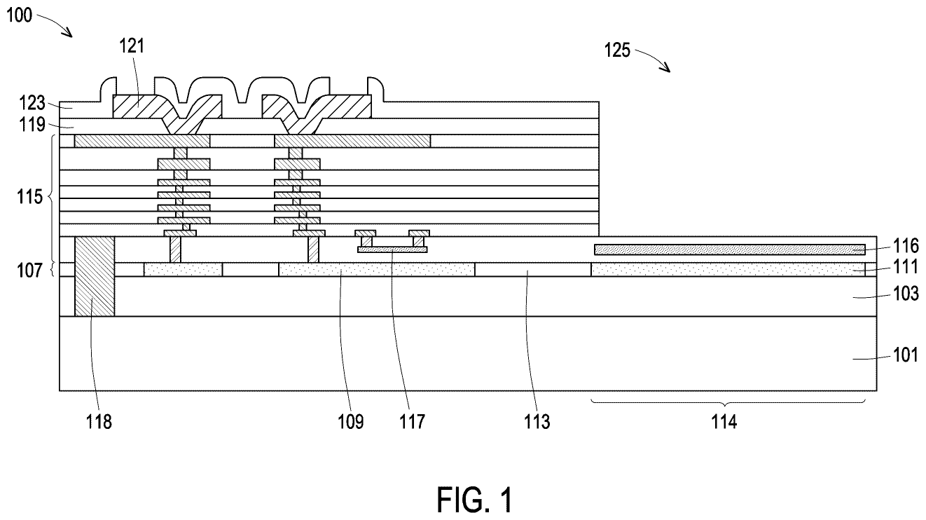

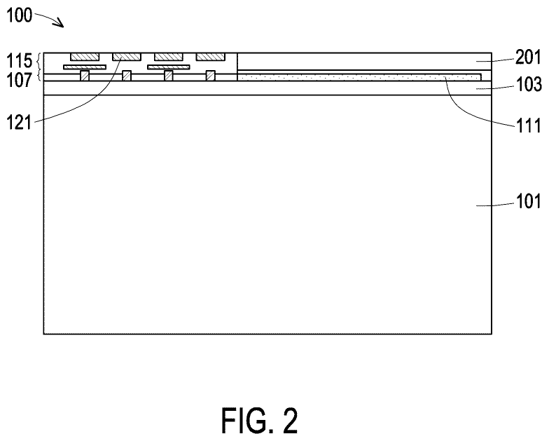

With reference now to FIG. 1, there is illustrated an initial structure of an optical interposer 100 (seen in FIG. 2), which may be a N65 wafer in accordance with some embodiments. In an initial structure, the optical interposer 100 is a More than Moore photonic integrated circuit (PIC) and comprises at an initial stage of manufacturing a first substrate 101, a first insulator layer 103, and a layer of material for a first active layer 107 of first optical components 109. In an embodiment, at a beginning of the manufacturing process of the optical interposer 100, the first substrate 101, the first insulator layer 103, and the layer of material for the first active layer 107 of first optical components 109 may collectively be part of a silicon-on-insulator (SOI) substrate. Looking first at the first substrate 101, the first substrate 101 may be a semiconductor material such as silicon or germanium, a dielectric material such as glass, or any other suitable material that allows for structural support of overlying devices.

The first insulator layer 103 may be a dielectric layer that separates the first substrate 101 from the overlying first active layer 107 and can additionally, in some embodiments, serve as a portion of cladding material that surrounds the subsequently manufactured first optical components 109 (discussed further below). In an embodiment the first insulator layer 103 may be silicon oxide, silicon nitride, germanium oxide, germanium nitride, combinations of these, or the like, formed using a method such as implantation (e.g., to form a buried oxide (BOX) layer) or else may be deposited onto the first substrate 101 using a deposition method such as chemical vapor deposition, atomic layer deposition, physical vapor deposition, combinations of these, or the like, to a thickness of about 1.6 μm. However, any suitable material and method of manufacture may be used.

The material for the first active layer 107 is initially (prior to patterning) a conformal layer of material that will be used to begin manufacturing the first active layer 107 of the first optical components 109. In an embodiment the material for the first active layer 107 may be a translucent material that can be used as a core material for the desired first optical components 109, such as a semiconductor material such as silicon, germanium, silicon germanium, combinations of these, or the like, while in other embodiments the material for the first active layer 107 may be a dielectric material such as silicon nitride or the like, although in other embodiments the material for the first active layer 107 may be III-V materials, lithium niobate materials, or polymers. In embodiments in which the material of the first active layer 107 is deposited, the material for the first active layer 107 may be deposited using a method such as epitaxial growth, chemical vapor deposition, atomic layer deposition, physical vapor deposition, combinations of these, or the like. In other embodiments in which the first insulator layer 103 is formed using an implantation method, the material of the first active layer 107 may initially be part of the first substrate 101 prior to the implantation process to form the first insulation layer 103. However, any suitable materials and methods of manufacture may be utilized to form the material of the first active layer 107.

FIG. 1 also illustrates that, once the material for the first active layer 107 is ready, the first optical components 109 for the first active layer 107 are manufactured using the material for the first active layer 107. In embodiments the first optical components 109 of the first active layer 107 may include such components as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring modulators, etc.), amplifiers, multiplexors, demultiplexors, optical-to-electrical converters (e.g., P-N junctions), electrical-to-optical converters, lasers, combinations of these, or the like. However, any suitable first optical components 109 may be used.

To begin forming the first active layer 107 of first optical components 109 from the initial material, the material for the first active layer 107 may be patterned into the desired shapes for the first active layer 107 of first optical components 109. In an embodiment the material for the first active layer 107 may be patterned using, e.g., one or more photolithographic masking and etching processes. However, any suitable method of patterning the material for the first active layer 107 may be utilized. For some of the first optical components 109, such as waveguides or edge couplers, the patterning process may be all or at least most of the manufacturing that is used to form these first optical components 109 components.

For those components that utilize further manufacturing processes, such as Mach-Zehnder silicon-photonic switches that utilize resistive heating elements, additional processing may be performed either before or after the patterning of the material for the first active layer 107. For example, implantation processes, additional deposition and patterning processes for different materials (e.g., resistive heating elements, III-V materials for converters), combinations of all of these processes, or the like, can be utilized to help further the manufacturing of the various desired first optical components 109. In a particular embodiment, in some embodiments an epitaxial deposition of a semiconductor material such as germanium (used, e.g., for electricity/optics signal modulation and transversion) may be performed on a patterned portion of the material of the first active layer 107. In such an embodiment the semiconductor material may be epitaxially grown in order to help manufacture, e.g., a photodiode for an optical-to-electrical converter. All such manufacturing processes and all suitable first optical components 109 may be manufactured, and all such combinations are fully intended to be included within the scope of the embodiments.

In the particular embodiment illustrated in FIG. 1, the first active layer 107 of the first optical components 109 specifically includes a first edge coupler 111. The first edge coupler 111 may be formed within an edge region 114 of the first active layer 107 and may be formed as described above with respect to the remainder of the first optical components 109 (e.g., patterning the material for the first active layer 105) to a thickness of about 0.27 μm. However, in other embodiments the first edge coupler 111 may be formed sequentially from the other first optical components 109. Any suitable materials, thicknesses, and methods of formation may be utilized.

FIG. 1 further illustrates that, once the individual first optical components 109 of the first active layer 107 have been formed, a second insulator layer 113 may be deposited to cover the first optical components 109 and provide additional cladding material. In an embodiment the second insulator layer 113 may be a dielectric layer that separates the individual components of the first active layer 107 from each other and from the overlying structures and can additionally serve as another portion of cladding material that surrounds the first optical components 109. In an embodiment the second insulator layer 113 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the second insulator layer 113 has been deposited, the material may be planarized using, e.g., a chemical mechanical polishing process in order to either planarize a top surface of the second insulator layer 113 (in embodiments in which the second insulator layer 113 is intended to fully cover the first optical components 109) or else planarize the second insulator layer 113 with top surfaces of the first optical components 109. However, any suitable material and method of manufacture may be used.

Once the first optical components 109 of the first active layer 107 have been manufactured and the second insulator layer 113 has been formed, first metallization layers 115 are formed in order to electrically connect the first active layer 107 of first optical components 109 to control circuitry, to each other, and to subsequently attached devices. In an embodiment the first metallization layers 115 are formed of alternating layers of dielectric and conductive material and may be formed through any suitable processes (such as deposition, damascene, dual damascene, etc.). In particular embodiments there may be multiple layers of metallization (e.g., six metallization layers) used to interconnect the various first optical components 109, but the precise number of first metallization layers 115 is dependent upon the design of the optical interposer 100.

Additionally, during the manufacture of the first metallization layers 115, one or more second optical components 117 may be formed as part of the first metallization layers 115. In some embodiments the second optical components 117 of the first metallization layers 115 may include such components as couplers (e.g., edge couplers, grating couplers, etc.) for connection to outside signals, optical waveguides (e.g., ridge waveguides, rib waveguides, buried channel waveguides, diffused waveguides, etc.), optical modulators (e.g., Mach-Zehnder silicon-photonic switches, microelectromechanical switches, micro-ring modulators, etc.), amplifiers, multiplexors, demultiplexors, optical-to-electrical converters (e.g., P-N junctions), electrical-to-optical converters, lasers, combinations of these, or the like. However, any suitable optical components may be used for the one or more second optical components 117.

In an embodiment the one or more second optical components 117 may be formed by initially depositing a material for the one or more second optical components 117. In an embodiment the material for the one or more second optical components 117 may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, any suitable material and any suitable method of deposition may be utilized.

Once the material for the one or more second optical components 117 has been deposited or otherwise formed, the material may be patterned into the desired shapes for the one or more second optical components 117. In an embodiment the material of the one or more second optical components 117 may be patterned using, e.g., one or more photolithographic masking and etching processes. However, any suitable method of patterning the material for the one or more second optical components 117 may be utilized.

For some of the one or more second optical components 117, such as waveguides or edge couplers, the patterning process may be all or at least most manufacturing that is used to form these components. Additionally, for those components that utilize further manufacturing processes, such as Mach-Zehnder silicon-photonic switches that utilize resistive heating elements, additional processing may be performed either before or after the patterning of the material for the one or more second optical components 117. For example, implantation processes, additional deposition and patterning processes for different materials, combinations of all of these processes, or the like, and can be utilized to help further the manufacturing of the various desired one or more second optical components 117. All such manufacturing processes and all suitable one or more second optical components 117 may be manufactured, and all such combinations are fully intended to be included within the scope of the embodiments.

In the particular embodiment illustrated in FIG. 1, the first metallization layers 115 with the second optical components 117 specifically includes a second edge coupler 116. The second edge coupler 116 may be formed within the edge region 114 of the first metallization layers 115 and may be formed as described above with respect to the remainder of the first optical components 109 (e.g., patterning the material for the one or more second optical components 117) to a thickness of about 0.4 μm. However, in other embodiments the second edge coupler 116 may be formed sequentially from the other second optical components 117. Any suitable materials, thicknesses, and methods of formation may be utilized.

Additionally, at any desired point within the manufacturing process of the first metallization layers 115, first through device vias (TDVs) 118 may be formed. In an embodiment the first through device vias 118 extend through the first active layer 107 so as to provide a quick passage of power, data, and ground through the optical interposer 100. In an embodiment the first through device vias 118 may be formed by initially forming through device via openings into the optical interposer 100. The through device via openings may be formed by applying and developing a suitable photoresist (not shown), and removing portions that are exposed.

Once the through device via openings have been formed within the optical interposer 100, the through device via openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may also be used.

Once the liner has been formed along the sidewalls and bottom of the through device via openings, a barrier layer (also not independently illustrated) may be formed and the remainder of the through device via openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the through device via openings. Once the through device via openings have been filled, excess liner, barrier layer, seed layer, and first conductive material outside of the through device via openings may be removed through a planarization process such as chemical mechanical polishing (CMP), although any suitable removal process may be used.

Once the one or more second optical components 117 and the first through device vias 118 of the first metallization layers 115 have been manufactured, a first passivation layer 119, first contacts 121, and a second passivation layer 123 are formed in connection with the first metallization layers 115. In an embodiment the first passivation layer 119 is formed of a material used to electrically isolate and protect the structure from overlying structures, and may be a material such as silicon oxide, silicon nitride, silicon oxynitride, combinations of these, or the like, and may be deposited using a chemical vapor deposition process, an atomic layer deposition process, a physical vapor deposition process, combinations of these, or the like. However, any suitable materials and any suitable methods of deposition may be utilized.

Once deposited the first passivation layer 119 is patterned in order to form openings through the first passivation layer 119 and expose conductive portions of the first metallization layers 115. In an embodiment the patterning may be performed using, e.g., a photolithographic masking and etching process. However, any suitable patterning process may be utilized.

After the patterning the first contacts 121 are formed through the openings and in electrical connection with the first metallization layers 115. In an embodiment the first contacts 121 may be a conductive material such as copper, aluminum, gold, tungsten, combinations of these, or the like, deposited using a method such as depositing a seed layer, patterning a photolithographic mask over the seed layer, plating the conductive material, removing the photolithographic mask, and etching the now exposed seed layer. In other embodiments the first contacts 121 may be formed by initially forming an opening in the first passivation layer 119, depositing or plating conductive material in the opening, and then planarizing the conductive material. However, any suitable material or method of manufacture may be utilized.

Once the first contacts 121 have been formed, a second passivation layer 123 is formed and patterned over the first contacts 121. In an embodiment the second passivation layer 123 may be an insulative and protecting material such as silicon oxide (SiO₂), silicon nitride, silicon oxynitride, combinations of these, or the like, deposited using a deposition process such as chemical vapor deposition, atomic layer deposition, physical vapor deposition combinations of these, or the like, and may be patterned using, e.g., a photolithographic masking and etching process. However, any suitable materials and methods of manufacture may be utilized.

FIG. 1 additionally illustrates that, once the second passivation layer 123 has been formed and patterned, a first opening 125 may be formed over the first edge coupler 111 and/or the second edge coupler 116 through a majority of the first metallization layers 115. In an embodiment the first opening 125 may be formed using one or more photolithographic masking and etching process. However, any suitable methods may be utilized. Once the first contacts 121 have been exposed, a wafer acceptance test (WAT) may be performed to ensure that the structure meets the manufacturing requirements.

FIG. 2 illustrates a pulled out view of the structure of FIG. 1 which illustrates a gap fill of the first opening 125 with a first gap-fill material 201 to provide additional support. In an embodiment the first gap-fill material 201 may be a material such as silicon oxide, silicon nitride, silicon oxynitride, combinations of these, or the like, deposited to fill and overfill the spaces around the first gap-fill material 201. However, any suitable material and method of deposition may be utilized.

Once the first gap-fill material 201 has been deposited, the first gap-fill material 201 may be planarized in order to expose the first contacts 121. In an embodiment the planarization process may be a chemical mechanical planarization process, a grinding process, or the like. However, any suitable planarization process may be utilized.

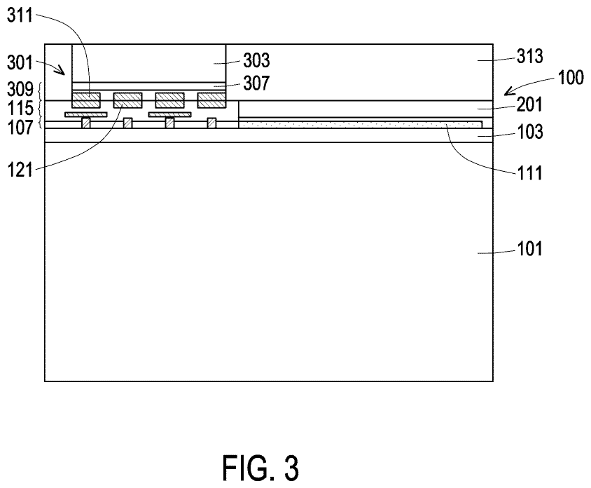

FIG. 3 illustrates a bonding of a first semiconductor device 301 to the first contacts 121 of the optical interposer 100. In some embodiments, the first semiconductor device 301 is an electronic integrated circuit (EIC—e.g., a device without optical devices) such as an N5 or N7 EIC and may have a semiconductor substrate 303, a layer of active devices (not separately illustrated in FIG. 3), an overlying interconnect structure 307, a first bonding layer 309, and associated bond pads 311. In an embodiment the semiconductor substrate 303 may be similar to the first substrate 101 (e.g., a semiconductor material such as silicon or silicon germanium), the active devices 305 may be transistors, capacitors, resistors, and the like formed over the semiconductor substrate 303, the interconnect structure 307 may be similar to the first metallization layers 115 (without optical components), the first bonding layer 309 may be similar to the first passivation layer 119 and the first contacts 121. However, any suitable devices may be utilized.

In an embodiment the first semiconductor device 301 may be configured to work with the optical interposer 100 for a desired functionality. In some embodiments the first semiconductor device 301 may be a high bandwidth memory (HBM) module, an xPU, a logic die, a 3DIC die, a CPU, a GPU, a SoC die, a MEMS die, combinations of these, or the like. Any suitable device with any suitable functionality, may be used, and all such devices are fully intended to be included within the scope of the embodiments.

In an embodiment the first semiconductor device 301 and the first contacts 121 of the optical interposer 100 may be bonded using a dielectric-to-dielectric and metal-to-metal bonding process. In a particular embodiment which utilizes a dielectric-to-dielectric and metal-to-metal bonding process, the process may be initiated by activating the surfaces of the first bonding layer 309 and the surfaces of the first contacts 121 of the optical interposer 100. Activating the top surfaces of the first contacts 121 of the optical interposer 100 and the first bonding layer 309 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the first contacts 121 of the optical interposer 100 and the first bonding layer 309.

After the activation process the optical interposer 100 and the first semiconductor device 301 may be cleaned using, e.g., a chemical rinse, and then the first semiconductor device 301 is aligned and placed into physical contact with the optical interposer 100. The optical interposer 100 and the first semiconductor device 301 are then subjected to thermal treatment and contact pressure to bond the optical interposer 100. For example, the optical interposer 100 and the first semiconductor device 301 may be subjected to a pressure of about 200 kPa or less, and a temperature between about 25° C. and about 250° C. to fuse the optical interposer 100 and the first semiconductor device 301. The optical interposer 100 and the first semiconductor device 301 may then be subjected to a temperature at or above the eutectic point for material of the first contacts 121 and the bond pads 311, e.g., between about 150° C. and about 650° C., to fuse the metal. In this manner, the optical interposer 100 and the first semiconductor device 301 forms a dielectric-to-dielectric and metal-to-metal bonded device. In some embodiments, the bonded dies are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

FIG. 3 additionally illustrates that, once the first semiconductor device 301 has been bonded, a second gap-fill material 313 is deposited in order to fill the space around the first semiconductor device 301 and provide additional support. In an embodiment the second gap-fill material 313 may be a material such as silicon oxide, silicon nitride, silicon oxynitride, combinations of these, or the like, deposited to fill and overfill the spaces around the first semiconductor device 301. However, any suitable material and method of deposition may be utilized.

Once the second gap-fill material 313 has been deposited, the second gap-fill material 313 may be planarized in order to expose the first semiconductor device 301. In an embodiment the planarization process may be a chemical mechanical planarization process, a grinding process, or the like. However, any suitable planarization process may be utilized.

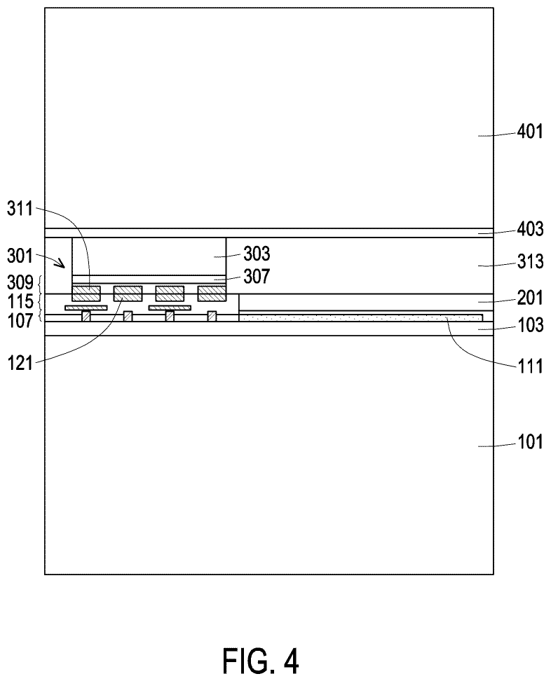

FIG. 4 illustrates an attachment of a support substrate 401 to the first semiconductor device 301 and the second gap-fill material 313. In an embodiment the support substrate 401 may be a support material that is transparent to the wavelength of light that is desired to be used, such as silicon, and may be attached using, e.g., a bonding layer 403, such as an oxide bonding layer, bonded using, for example, a fusion bonding process. However, in other embodiments the support substrate 401 may be bonded to the first semiconductor device 301 and the second gap-fill material 313 using, e.g., an adhesive. Any suitable method of attaching the support substrate 401 may be used.

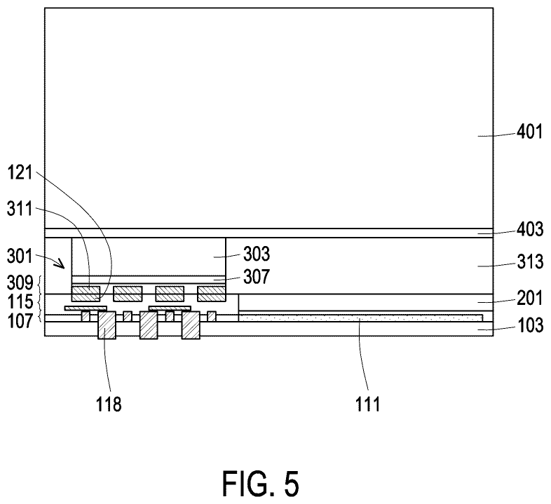

FIG. 5 illustrates a removal of the first substrate 101, thereby exposing the first insulator layer 103 and the first TDVs 118. In an embodiment the first substrate 101 may be removed using a planarization process, such as a chemical mechanical polishing process, a grinding process, one or more etching processes, combinations of these, or the like. However, any suitable method may be used in order to remove the first substrate 101.

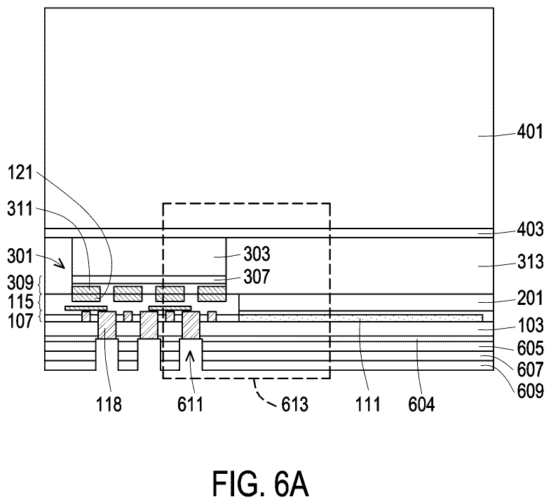

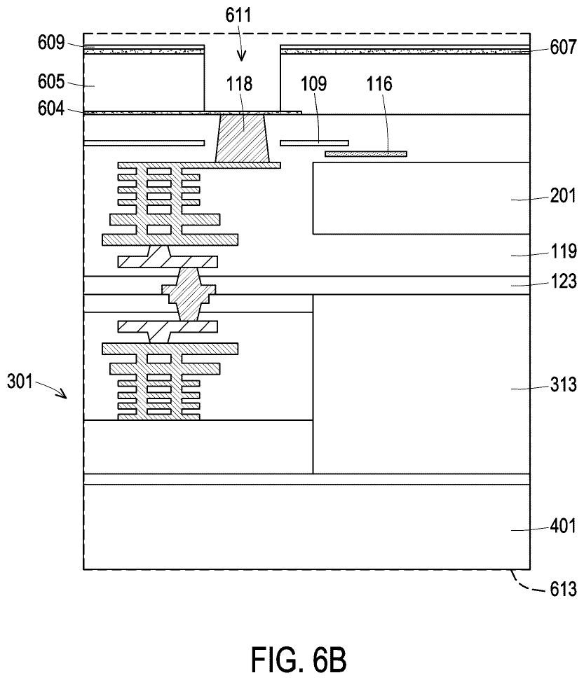

FIGS. 6A-6B illustrate that, once the first substrate 101 has been removed, a first buffer layer 604, a third passivation layer 605, a fourth passivation layer 607, and a fifth passivation layer 609 may be deposited (with only a single one of the first edge coupler 111 and the second edge coupler 116 illustrated for clarity). FIG. 6B illustrates a close-up, flipped view of the dashed box 613 in FIG. 6A. The first buffer layer 604 may be a material such as silicon nitride, silicon oxide, silicon oxynitride, combinations of these, or the like, deposited using a deposition method such as chemical vapor deposition, physical vapor deposition, atomic layer deposition, or the like. The first buffer layer 604 may be deposited to a thickness of between about 100 Å and about 750 Å, and then patterned using, e.g., a photolithographic masking and etching process. However, any suitable material and method may be utilized.

In an embodiment the third passivation layer 605 may be an insulative and protecting material such as silicon oxide (SiO₂), silicon nitride, silicon oxynitride, combinations of these, or the like, deposited using a deposition process such as chemical vapor deposition, atomic layer deposition, physical vapor deposition combinations of these, or the like, to a thickness of between about 1 μm and about 10 μm. However, any suitable material and method of manufacture may be utilized.

The fourth passivation layer 607 is deposited over the third passivation layer 605 in order to help protect portions of the third passivation layer 605 during subsequent patterning processes. In an embodiment the fourth passivation layer 607 may be an insulative and protecting material that is different from the third passivation layer 605, such as by being silicon nitride, silicon oxide, silicon oxynitride, combinations of these, or the like, deposited using a deposition process such as chemical vapor deposition, atomic layer deposition, physical vapor deposition combinations of these, or the like, to a thickness of between about 1000 Å and about 8000 Å. However, any suitable material and method of manufacture may be utilized.

A fifth passivation layer 609 may be deposited in order to help with etching selectivity during subsequent etching processes. In an embodiment the fifth passivation layer 609 may be a metal material such as titanium, tantalum, titanium nitride, tantalum nitride, combinations of these, or the like, deposited using a deposition method such as chemical vapor deposition, physical vapor deposition, atomic layer deposition, combinations of these, or the like, to a thickness of between about 50 Å and about 1000 Å. However, any suitable material and methods may be used.

Once deposited, a patterning of the third passivation layer 605, the fourth passivation layer 607 and the fifth passivation layer 609 is performed in order to form second openings 611 through the fourth passivation layer 607 and the fifth passivation layer 609 to expose the first buffer layer 604 (e.g., silicon nitride). In an embodiment the patterning may be performed using, e.g., a photolithographic masking and etching process. However, any suitable patterning process may be utilized.

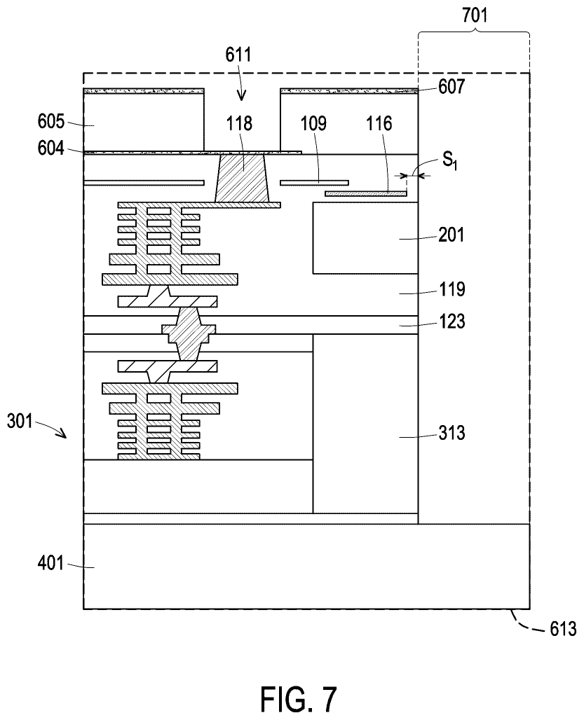

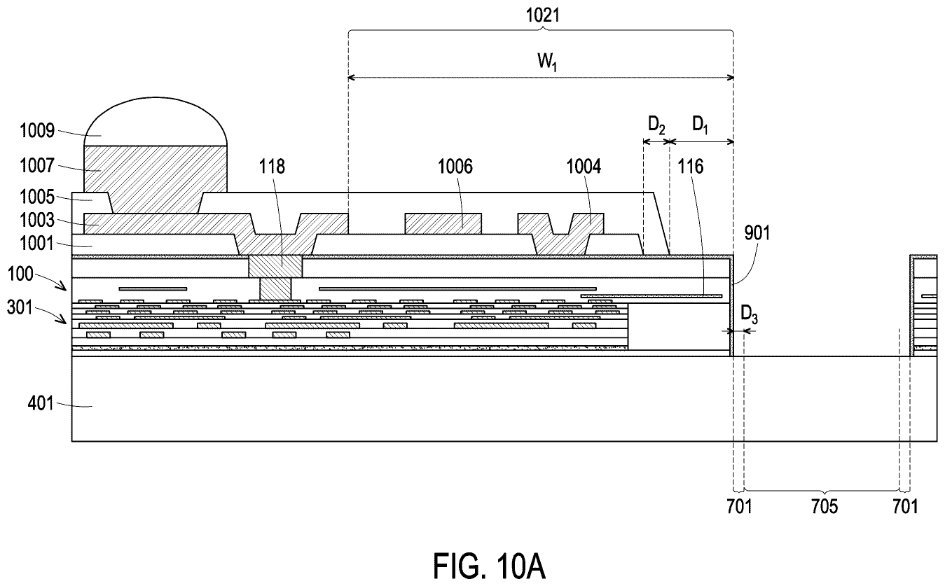

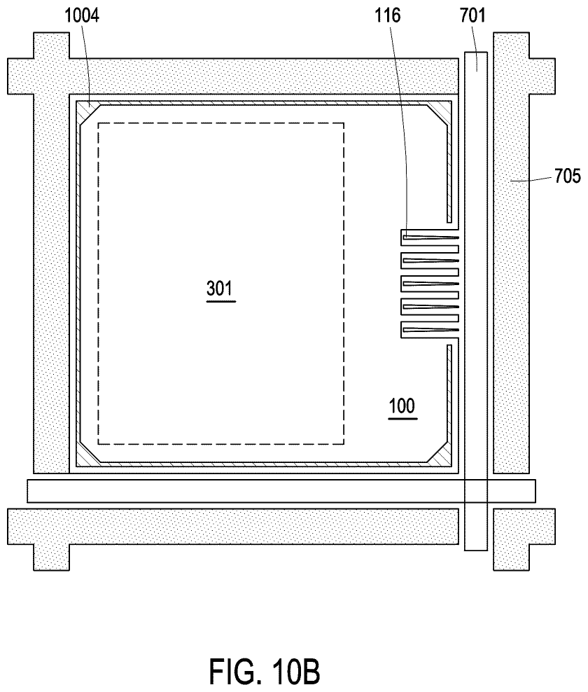

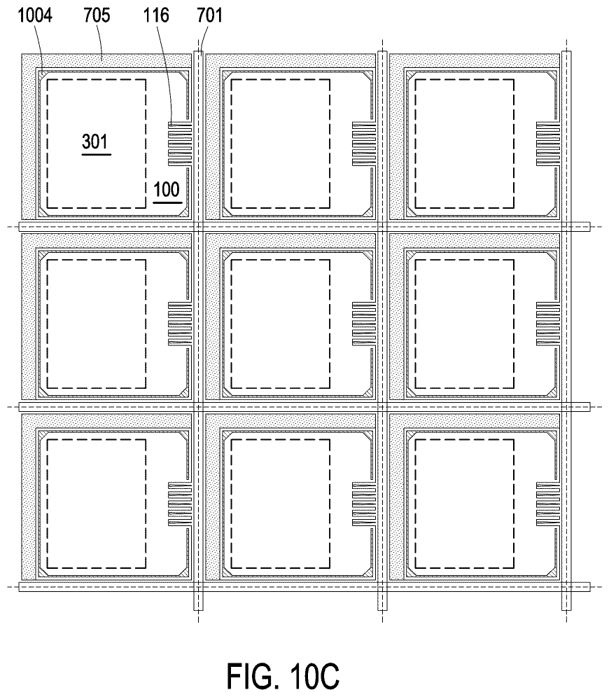

FIG. 7 illustrate formation of a first facet 701 and a scribe region 705 (not illustrated in FIG. 7 but illustrated and discussed further below with respect to FIG. 10A). In an embodiment the first facet 701 may be formed through the first insulator layer 103, the first active layer 105, the first gap-fill material 201, and the second gap-fill material 313. In an embodiment the first facet 701 may be formed using one or more photolithographic masking and etching processes, such as a two photoresist, two etch process. However, any suitable methods of forming the first facet 601 may be utilized.

In an embodiment the sidewall of the first facet 701 may be offset from the second edge coupler 116 by a first spacing S₁. In some embodiments the first spacer S₁ may be less than about 3 μm. However, any suitable spacing may be utilized.

Once the first facet 701 and the scribe region 705 have been formed, the fifth passivation layer 609 (e.g., titanium) may be removed. In an embodiment the fifth passivation layer 609 may be removed using one or more wet etching processes. However, any suitable removal process may be utilized.

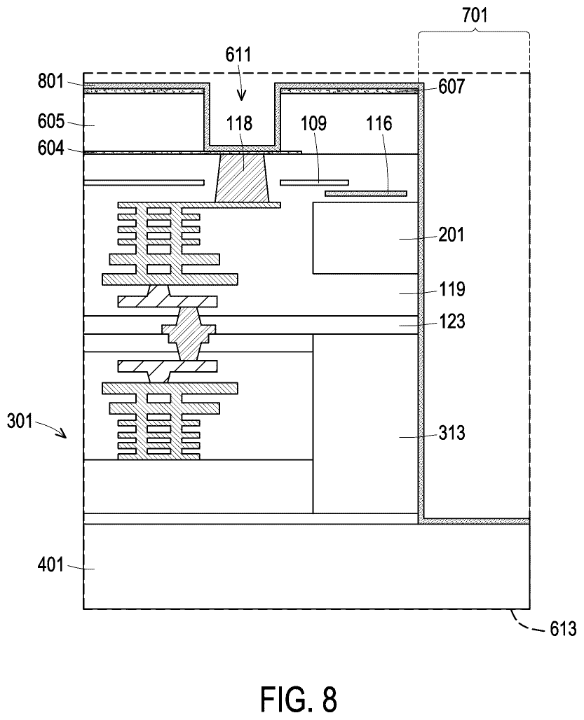

FIG. 8 illustrates a formation of a first spacer material 801 to line the first facet 701 and the second openings 611. In an embodiment the first spacer material 801 may be a material such as silicon nitride, silicon oxide, silicon oxynitride, combinations of these, or the like, deposited using a deposition process such as chemical vapor deposition, physical vapor deposition, atomic layer deposition, or the like. The first spacer material 801 may be deposited to a thickness of between about 1000 Å and about 8000 Å. Additionally, by depositing the first spacer material 801 to line the second openings 611, in embodiment in which both the first buffer layer 604 and the first spacer material 801 are silicon nitride, then the combined thickness within the second openings 611 is about 3,750 Å (750 Å+3,000 Å). However, any suitable material, process, and thickness may be utilized.

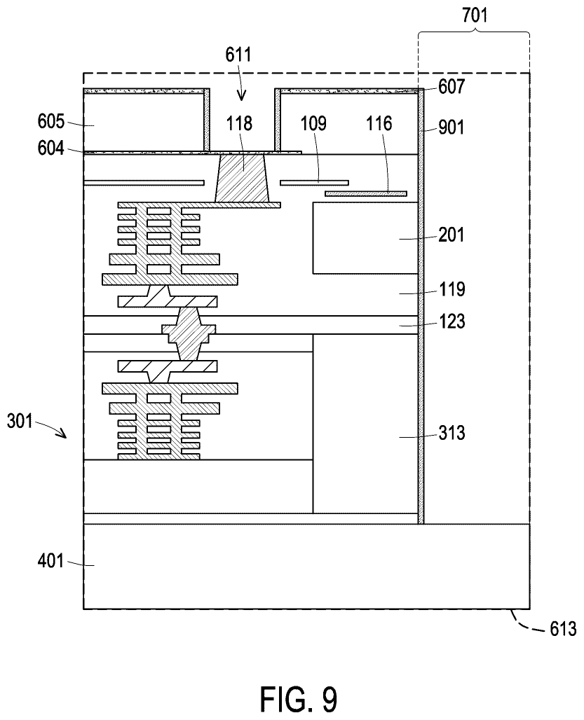

FIG. 9 illustrates a liner removal process in order to remove horizontal elements of the first spacer material 801, expose the first TDVs 118 through the first buffer layer 604, and form the first spacers 901. In an embodiment the liner removal process may be a low-rf power, dry etching process using etchants selective to the materials of the first spacer material 801 and the first buffer layer 604. As such, in an embodiment in which the first spacer 901 and the first buffer layer 604 are silicon nitride, the liner removal process may use an etchant such as CₓF_{y}. After the liner removal process the first spacer 901 may have a thickness of between about 50 Å and about 3,000 Å. However, any suitable thickness and processes may be utilized.

Additionally, once the first spacer material 801 has been removed from the horizontal portions of the first facet 701, the process may be continued in order to remove the first buffer layer 604 within the second openings 611. In an embodiment the process may be used to overetch and remove the material of the first buffer layer 604. However, in other embodiments a separate etch process may be used. Any suitable process or combinations of process may be used to expose the first TDVs 118.

FIG. 10A illustrates formation of a sixth passivation layer 1001, a first redistribution layer 1003, a seventh passivation layer 1005, second contact pads 1007, and first external connections 1009. In an embodiment the sixth passivation layer 1001 may be a polymer material such as polyimide or the like, deposited using a deposition method such as spin-on processes. However, any suitable materials and methods may be utilized.

Once the sixth passivation layer 1001 has been placed, a first redistribution layer 1003 may be formed to extend through the sixth passivation layer 1001. In an embodiment the sixth passivation layer 1001 may be patterned, a seed layer is deposited and covered by a patterned photolithographic material, a conductive material such as copper is plated onto the exposed portions of the seed layer, the patterned photolithographic material is removed, and exposed portions of the seed layer are removed. However, any suitable methods and materials may be utilized.

In a particular embodiment the first redistribution layer 1003 comprises conductive elements that route electrical signals (e.g., power, ground, signals, test signals, etc.) which are formed outside of a keep out zone (KOZ) 1021. Within the keep out zone 1021, no functional circuitry is formed within the first redistribution layer 1003. In particular embodiments the keep out zone 1021 may have a first width W₁ from the first spacer 901 to functional circuitry of between about 50 μm and about 500 μm. However, any suitable distance may be utilized.

However, the keep out zone 1021 is not completely devoid of conductive structures. In an embodiment, either simultaneously with or sequentially with the formation of the first redistribution layer 1003, a seal ring 1004 may be formed within the keep out zone 1021. In an embodiment the seal ring 1004 works not only to enhance the moisture resistance but also helps to ensure the overall yield by helping to ensure a good thickness uniformity of the subsequently applied seventh passivation layer 1005 near the first facet 701. The seal ring 1004 may be formed to extend through the sixth passivation layer 1001 using similar materials and processes as the first redistribution layer 1003, although any suitable methods and materials may be utilized.

In addition to the first redistribution layer 1003 and the seal ring 1004, a dummy portion 1006 may also be formed over the sixth passivation layer 1001 in the keep out zone 1021. In an embodiment the dummy portion 1006 is not electrically connected to the underlying metallization layers, but is instead used as a physical structure to help ensure that the subsequently applied seventh passivation layer 1005 has a good uniformity of thickness. The dummy portion 1006 may be formed using similar materials and processes as the first redistribution layer 1003, and may be formed with simultaneously with or subsequently to the first redistribution layer 1003, although any suitable methods and materials may be utilized.

The seventh passivation layer 1005 is formed to cover the first redistribution layer 1003. In an embodiment the seventh passivation layer 1005 may be formed using similar materials and processes as the sixth passivation layer 1001. For example, the seventh passivation layer 1005 may be a material such as polyimide formed using a process such as a spin-on process and then cured. However, any suitable material and processes may be utilized.

The second contact pads 1007 may be formed to extend through the seventh passivation layer 1005 and make electrical contact with the first redistribution layer 1003. In an embodiment the seventh passivation layer 1005 may be patterned, a seed layer is deposited and covered by a patterned photolithographic material, a conductive material such as copper is plated onto the exposed portions of the seed layer, the patterned photolithographic material is removed, and exposed portions of the seed layer are removed. However, any suitable methods and materials may be utilized.

The first external connections 1009 may be conductive bumps (e.g., C4 bumps, ball grid arrays, microbumps, etc.) or conductive pillars utilizing materials such as solder and copper. In an embodiment in which the first external connections 1009 are contact bumps, the first external connections 1009 may comprise a material such as tin, or other suitable materials, such as silver, lead-free tin, or copper. In an embodiment in which the first external connections 1009 are tin solder bumps, the first external connections 1009 may be formed by initially forming a layer of tin through such commonly used methods such as evaporation, electroplating, printing, solder transfer, ball placement, etc. Once a layer of tin has been formed on the structure, a reflow may be performed in order to shape the material into the desired bump shape.

By forming and then patterning the seventh passivation layer 1005, the seventh passivation layer 1005 may be recessed from the sidewalls of the first spacer 901. In an embodiment the seventh passivation layer 1005 may be patterned to be recessed a first distance D₁ of between about 5 μm and about 100 μm. Additionally, the sidewall of the seventh passivation layer 1005 may be inclined as illustrated (e.g., due to curing), but may also be vertical in other embodiments. However, any suitable distance and shapes may be utilized.

Additionally, by recessing the seventh passivation layer 1005, the seventh passivation layer 1005 may extend away from the sixth passivation layer 1001. In an embodiment the seventh passivation layer 1005 may extend a second distance D₂ of between about 2 μm and about 10 μm. However, any suitable distance may be utilized.

Looking at the first facet 701 and the scribe region 705, the first facet 701 extends from a sidewall of the first spacer 901 towards the scribe region 705 a third distance D₃. In an embodiment the third distance D₃ may be less than about 34 μm, less than about 30 μm, or even less than about 10 μm. However, any suitable distance may be utilized.

FIG. 10B illustrates a top down view of the optical interposer 100, the first semiconductor device 301, the seal ring 1004, and the first facet 701, with certain elements either removed or visible in order to better illustrate the relevant positions of the components. In the embodiment illustrated the first facet 701 is formed adjacent to the second edge couplers 116 (with five of the second edge couplers 116 illustrated in FIG. 10B). However, in other embodiments the first edge couplers 111 may be utilized, or other numbers of edge couplers can be used).

Additionally, in some embodiments the seal ring 1004 is formed so as to not overlap the first edge couplers 111 in the top down view. Without such an overlap, the seal ring 1004 avoids any optical interference that may occur during transmission of optical signals into and out of the second edge couplers 116. However, in other embodiments the seal ring 1004 may be formed in a continuous ring.

Further, if desired, the first facet 701 may be formed adjacent to more the one side of the optical interposer 100. For example, in the embodiment illustrated in FIG. 10B, the first facets 701 may be formed adjacent to two sides, while the first facets 701 may not be formed adjacent to two other sides of optical interposer 100. The first facet 701 may be formed adjacent to any number of sides of the optical interposer, and all such numbers are fully intended to be included within the scope of the embodiments.

FIG. 10C illustrates a top down view of multiple ones of the optical interposer 100 and the first semiconductor device 301 formed on a single wafer. As can be seen, the scribe lines 1011 extend between the individual devices, with the first facets 701 being located along one or more sides of the optical interposer 100 between the optical interposer 100 and the scribe lines 1011.

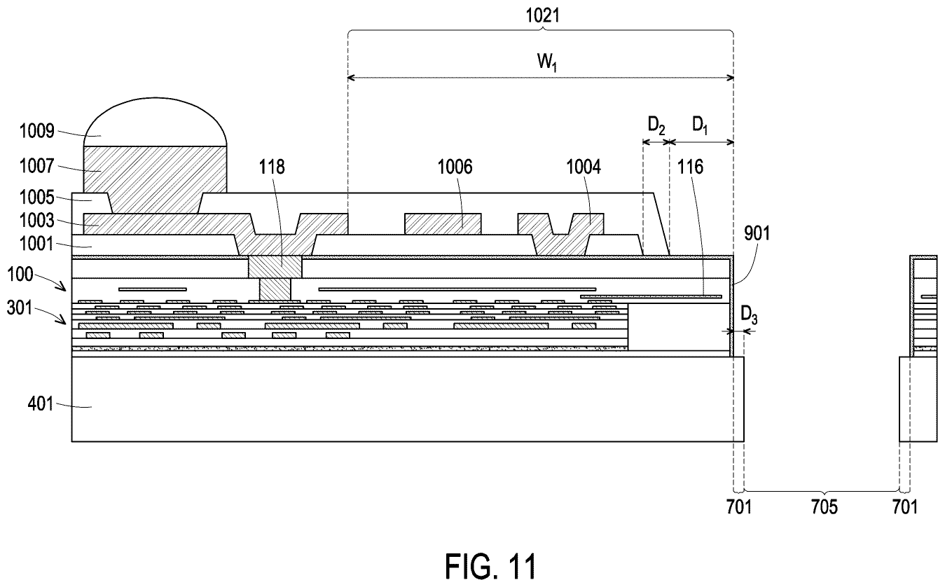

FIG. 11 illustrates that, once the first external connections 1009 have been formed, a chip probe test may be performed and the structure may be singulated through the scribe regions 705. In an embodiment the singulation may be performed by using a saw blade (not separately illustrated) to slice through the support substrate 401. However, as one of ordinary skill in the art will recognize, utilizing a saw blade for the dicing is merely one illustrative embodiment and is not intended to be limiting. Any method for performing the singulation, such as utilizing one or more etches or plasma dicing, may be utilized. These methods and any other suitable methods may be utilized to singulate the structure and a final test may be performed.

Of course, while the precise steps in the precise order described above may be used in order to manufacture the devices as described, this is intended to be illustrative and is not intended to limit the embodiments to only that order which is described. Rather, the individual steps may be performed in any suitable order. For example, in other embodiments the singulation may be performed prior to formation of the first redistribution layer 1003. All such steps and all such orders are fully intended to be included within the scope of the embodiments.

By utilizing the seal ring 1004 along with the first spacer 901, a moisture barrier can be formed that helps to ensure a good reliability with an edge coupler based COUPE. Additionally, the use of the seal ring 1004 helps to provide a good uniformity of thickness for the overlying seventh passivation layer 1005. As such, by being able to use the edge couplers with a higher reliability, a higher bandwidth device with a larger reliability can be achieved, helping to ensure a larger electrical yield.

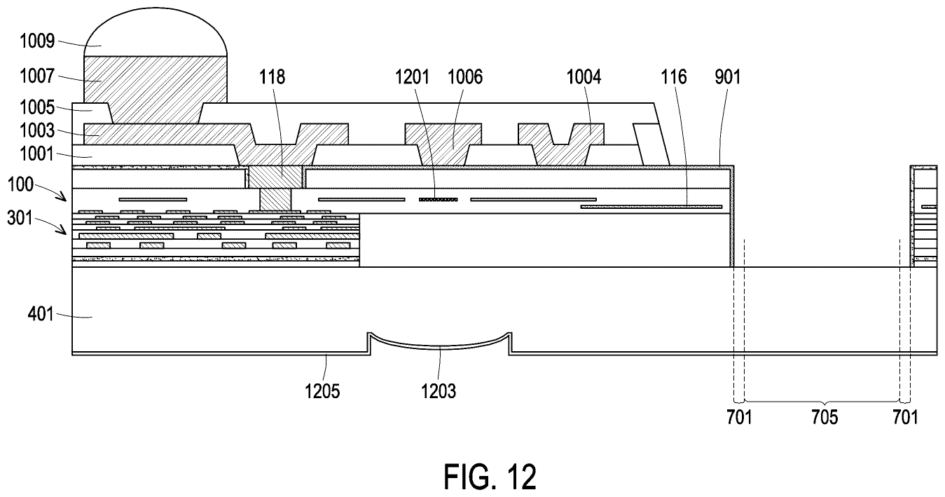

FIG. 12 illustrates another embodiment which utilizes a first grating couplers 1201 in addition to the first edge couplers 111 and/or the second edge couplers 116. In an embodiment the first grating couplers 1201 may be used to test the yield of the assemblies prior to a final connection of the device to external devices. In an embodiment the first grating couplers 1201 may be formed as part of the second optical components 117 of the first metallization layers 115 or else may be formed as part of the first active layer 107 of first optical components 109.

In this embodiment the support substrate 401 may be modified in order to help focus optical signals to the first grating couplers 1201. For example, the support substrate 401 may comprise a first lens 1203 positioned to receive and focus optical signals towards the first grating couplers 1201. In an embodiment the first lens 1203 is formed within the support substrate 401. In an embodiment the first lens 1203 may be formed by shaping the material of the support substrate 401 (e.g., silicon) using masking and etching processes. However, any suitable process may be utilized.

Additionally, if desired, a first anti-reflective coating (ARC) 1205 may be formed on the first lens 1203. In an embodiment the first ARC 1205 may be one or more layers of materials which help to prevent undesired reflections as light is focused through the first lens 1203. In a particular embodiment the one or more layers of materials may be materials such as silicon oxide, silicon nitride, combinations of these, or the like, formed using processes such as chemical vapor deposition, atomic layer deposition, physical vapor deposition, oxidation, nitridation, combinations of these, or the like.

In a particular embodiment the first ARC 1205 may be formed using a first layer of silicon oxide and a first layer of silicon nitride formed over the first layer of silicon oxide. A second layer of silicon oxide and a second layer of silicon nitride are deposited over the first layer of silicon oxide and the first layer of silicon nitride, forming an alternating stack of silicon oxide and silicon nitride. Once all of the desired layers have been deposited, the layers may be patterned using, e.g., a photolithographic masking and etching process. However, any suitable combinations of materials and processes may be utilized.

Additionally, in some embodiments the dummy portion 1006 may be manufactured and positioned in order to help the first grating couplers 1201. For example, the dummy portion 1006 may be formed to extend through the sixth passivation layer 1001 over the first grating couplers 1201 and positioned in order to reflect optical signals that may pass through the first grating couplers 1201 back to the first grating couplers 1201. As such, the dummy portion 1006 may be used in order to increase the capture efficiency of the first grating couplers 1201.

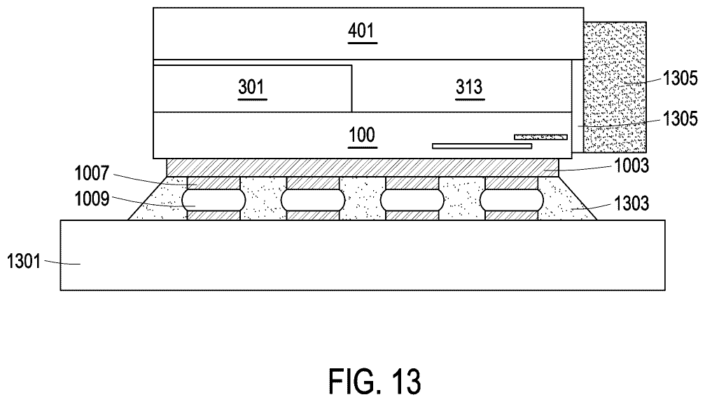

FIG. 13 illustrates a bonding of the first redistribution layer 1003 to a substrate 1301, such as an interposer substrate or printed circuit board. In an embodiment in which the substrate 1301 is an interposer substrate, substrate 1301 comprises a second substrate and second through device vias (not separately illustrated in FIG. 13). The second substrate may comprise a material that allows for visual transparency with high dimensional stability under thermal loads, and still has a coefficient of thermal expansion which is close to the silicon found in other parts of the device. In particular embodiments the second substrate may be formed of a material such as glass, polymer, epoxy, combinations of these, or the like. However, any suitable material may be utilized.

The second through device vias may be formed to extend through the second substrate and provide an electrical connection between a first side of the second substrate to a second side of the second substrate. In an embodiment the second through device vias may be formed using similar processes and similar materials as the first through device vias 118, such as forming an opening, depositing conductive material within the opening, and then thinning to expose the conductive material. However, any suitable methods and materials may be utilized.

A second metallization layer is formed over a first side of the second substrate. In an embodiment the second metallization layer may be formed as described above with respect to the first metallization layers, such as being alternating layers of dielectric and conductive materials using damascene processes, dual damascene process, or the like. In other embodiments, the second metallization layer may be formed using a plating process to form and shape conductive material, and then cover the conductive material with a dielectric material. However, any suitable structures and methods of manufacture may be utilized.

A third metallization layer is also formed on an opposite side of the second substrate from the second metallization layer. In an embodiment the third metallization layer may be formed as described above with respect to the first metallization layers, such as being alternating layers of dielectric and conductive materials using damascene processes, dual damascene process, or the like. In other embodiments, the third metallization layer may be formed using a plating process to form and shape conductive material, and then cover the conductive material with a dielectric material. However, any suitable structures and methods of manufacture may be utilized.

The optical interposer 100 may be bonded to the second metallization layer using, e.g., the first external connections 1009. In an embodiment the first external connections 1009 may be aligned with corresponding conductive connections on the second metallization layer. Once aligned the first external connections 1009 may then be reflowed in order to bond the optical interposer 100 to the substrate 1301. However, any suitable bonding process may be used to connect the optical interposer 100 to the substrate 1301.

Once bonded, a first underfill 1303 may be placed around the first external connections 1009. In an embodiment the first underfill 1303 is a protective material used to cushion and support the structure from operational and environmental degradation, such as stresses caused by the generation of heat during operation. The first underfill 1303 may be placed using an injection process with capillary action or may be otherwise formed, and the first underfill 1303 may, for example, comprise a liquid epoxy that is dispensed then cured to harden.

FIG. 13 additionally illustrates an attachment of a fiber array unit 1305 to the optical interposer 100 to provide an ingress and egress to optical signals (not illustrated in FIG. 13). In an embodiment the fiber array unit 1305 receives optical fibers, arranges the optical fibers with a fiber sheath, and directs the optical signals towards the first edge couplers 111 and/or the second edge couplers 116. The fiber array unit 1305 additionally will receive the optical signals from the first edge couplers 111 and/or the second edge couplers 116 and route them to the optical fibers, which will carry the optical signals away from the device.

In an embodiment the fiber array unit 1305 can be attached by initially positioning the optical fibers within the fiber array unit 1305 to be aligned with the first edge couplers 111 and/or the second edge couplers 116. Once the optical fibers have been aligned, the fiber array unit 1305 may be attached using, e.g., an optional optical glue 1307. In some embodiments, the optical glue 1307 comprises a polymer material such as epoxy-acrylate oligomers, and may have a refractive index between about 1 and about 3. In other embodiments, the optional optical glue 1307 may be excluded and the gap between the fiber array unit 1305 and the optical interposer 100 may be filled by an ambient environment, such as air.

By utilizing the seal ring 1004 along with the first spacer 901, a moisture barrier can be formed that helps to ensure a good reliability with an edge coupler based COUPE. Additionally, the use of the seal ring 1004 helps to provide a good uniformity of thickness for the overlying seventh passivation layer 1005. As such, by being able to use the edge couplers with a higher reliability, a higher bandwidth device with a larger reliability can be achieved, helping to ensure a larger electrical yield.

In an embodiment, a method of manufacturing an optical device includes: receiving a first optical interposer bonded to a first semiconductor device; attaching a support substrate to the first semiconductor device; forming a facet recess to recess a sidewall of the first optical interposer and expose the support substrate; and forming a first spacer along a sidewall of the first optical interposer after the forming the facet recess. In an embodiment the first spacer further includes: depositing a first buffer layer over a through device via; depositing a first passivation layer over the first buffer layer; exposing the first buffer layer through the first passivation layer; depositing a first material for the first spacer; and performing a liner removal process to expose the through device via and form the first spacer. In an embodiment the first material is silicon nitride. In an embodiment the method further includes forming a first metallization layer after the forming the facet recess, the first metallization layer comprising a seal ring. In an embodiment after the forming the facet recess the first optical interposer comprises an edge coupler adjacent to the sidewall of the first facet recess. In an embodiment after the forming the facet recess the first optical interposer comprises a grating coupler. In an embodiment the support substrate comprises a first lens aligned with the grating coupler.

In another embodiment, a method of manufacturing an optical device includes: removing a first portion of a metallization layer over first optical components to form a first opening; depositing a first gap fill material into the first opening; bonding a first semiconductor device to the metallization layer; depositing a second gap fill material around the first semiconductor device; bonding a support substrate to the second gap fill material; after the bonding the support substrate, removing portions of the first gap fill material and the second gap fill material to form a first facet; and forming a first spacer along a sidewall of the first facet. In an embodiment the method further includes forming a first redistribution layer connected to the metallization layer after the forming the first spacer. In an embodiment the forming the first redistribution layer forms a seal ring. In an embodiment the forming the first redistribution layer forms a dummy portion. In an embodiment the dummy portion is located to reflect light to a grating coupler within the first optical components. In an embodiment the support substrate comprises a first lens aligned with the grating coupler. In an embodiment the method further includes attaching a fiber array unit aligned with an edge coupler through the first spacer.

In yet another embodiment an optical device includes: a first semiconductor device bonded to an optical interposer; a support substrate bonded to the first semiconductor device, wherein a sidewall of the optical interposer is offset from a sidewall of the support substrate; and a first spacer lining the sidewall of the optical interposer. In an embodiment the optical device further includes an edge coupler within the optical interposer adjacent to the first spacer. In an embodiment the optical device further includes a first redistribution layer in electrical contact with a metallization layer within the optical interposer. In an embodiment the first redistribution layer comprises a seal ring. In an embodiment the first redistribution layer comprises a dummy portion. In an embodiment the support substrate comprises a first lens aligned with a grating coupler within the optical interposer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an optical device, the method comprising:
receiving a first optical interposer bonded to a first semiconductor device;
attaching a support substrate to the first semiconductor device;
forming a facet recess to recess a sidewall of the first optical interposer and expose the support substrate; and
forming a first spacer along a sidewall of the first optical interposer after the forming the facet recess.

2. The method of claim 1, wherein the forming the first spacer further comprises:
depositing a first buffer layer over a through device via;
depositing a first passivation layer over the first buffer layer;
exposing the first buffer layer through the first passivation layer;
depositing a first material for the first spacer; and
performing a liner removal process to expose the through device via and form the first spacer.

3. The method of claim 2, wherein the first material is silicon nitride.

4. The method of claim 1, further comprising forming a first metallization layer after the forming the facet recess, the first metallization layer comprising a seal ring.

5. The method of claim 1, wherein after the forming the facet recess the first optical interposer comprises an edge coupler adjacent to the sidewall of the first facet recess.

6. The method of claim 5, wherein after the forming the facet recess the first optical interposer comprises a grating coupler.

7. The method of claim 6, wherein the support substrate comprises a first lens aligned with the grating coupler.

8. A method of manufacturing an optical device, the method comprising:
removing a first portion of a metallization layer over first optical components to form a first opening;
depositing a first gap fill material into the first opening;
bonding a first semiconductor device to the metallization layer;
depositing a second gap fill material around the first semiconductor device;
bonding a support substrate to the second gap fill material;
after the bonding the support substrate, removing portions of the first gap fill material and the second gap fill material to form a first facet; and
forming a first spacer along a sidewall of the first facet.

9. The method of claim 8, further comprising forming a first redistribution layer connected to the metallization layer after the forming the first spacer.

10. The method of claim 9, wherein the forming the first redistribution layer forms a seal ring.

11. The method of claim 10, wherein the forming the first redistribution layer forms a dummy portion.

12. The method of claim 11, wherein the dummy portion is located to reflect light to a grating coupler within the first optical components.

13. The method of claim 12, wherein the support substrate comprises a first lens aligned with the grating coupler.

14. The method of claim 8, further comprising attaching a fiber array unit aligned with an edge coupler through the first spacer.

15. An optical device comprising:
a first semiconductor device bonded to an optical interposer;
a support substrate bonded to the first semiconductor device, wherein a sidewall of the optical interposer is offset from a sidewall of the support substrate; and
a first spacer lining the sidewall of the optical interposer.

16. The optical device of claim 15, further comprising an edge coupler within the optical interposer adjacent to the first spacer.

17. The optical device of claim 15, further comprising a first redistribution layer in electrical contact with a metallization layer within the optical interposer.

18. The optical device of claim 17, wherein the first redistribution layer comprises a seal ring.

19. The optical device of claim 18, wherein the first redistribution layer comprises a dummy portion.

20. The optical device of claim 19, wherein the support substrate comprises a first lens aligned with a grating coupler within the optical interposer.
